(19) United States
(12) Patent Application Publication
(10) Pub. No.: US 2025/0318045 A1
(43) Pub. Date: Oct. 9, 2025

(54) FLEXIBLE PRINTED CIRCUIT AND DISPLAY MODULE

(71) Applicant: Wuhan Tianma Microelectronics Co., Ltd., Wuhan (CN)

(72) Inventors: Linfang JIANG, Wuhan (CN); Ning XU, Wuhan (CN)

(73) Assignee: Wuhan Tianma Microelectronics Co., Ltd., Wuhan (CN)

(21) Appl. No.: 19/245,744

(22) Filed: Jun. 23, 2025

(30) Foreign Application Priority Data
Feb. 26, 2025 (CN) 202510223330.5

(51) Int. Cl. H05K 1/02; H05K 1/18

(52) U.S. Cl. CPC H05K 1/0281; H05K 1/189; H05K 2201/10128

(57) ABSTRACT

Provided are a flexible printed circuit and a display module. In the flexible printed circuit, a first conductive film layer located on a first surface of a flexible substrate comprises a first conductive structure, and a second conductive film layer located on a second surface of the flexible substrate comprises a second conductive structure; along a direction perpendicular to a plane of the flexible printed circuit, the first conductive structure does not overlap with the first cover film, the second conductive structure does not overlap with the second cover film, the first conductive structure overlaps with the second conductive structure, and the first conductive film layer and the second conductive film layer do not overlap with a second portion; and at least a region of the first surface of the second portion close to the edge of the flexible printed circuit is attached to a stiffener structure.

### CROSS-REFERENCE TO RELATED APPLICATION

The present application claims priority to Chinese Patent Application No. 202510223330.5, filed on Feb. 26, 2025, the content of which is incorporated herein by reference in its entirety.

### TECHNICAL FIELD

The present disclosure relates to the field of display technology, and, in particular, to a flexible printed circuit and a display module.

### BACKGROUND

A flexible printed circuit (FPC), also referred to as a flexible board, is a circuit board manufactured by bonding a flexible substrate and conductive film layers together, where the conductive film layers are usually copper foils. The flexible printed circuit can be freely bent and lines on the flexible substrate are less prone to damage. Therefore, the flexible printed circuit is widely applied to electronic products and can meet the demands of the development of the electronic products to high density, thinning, and miniaturization. In conventional FPC, the electrical reliability and appearance reliability of the flexible printed circuit are aspects of concern and need improvement.

### SUMMARY

In view of the above, embodiments of the present disclosure provide a flexible printed circuit and a display module to solve the above problems.

In a first aspect, an embodiment of the present disclosure provides a flexible printed circuit including:
a flexible substrate including a first surface and a second surface opposite to each other; where the flexible substrate includes a first portion and a second portion connected to each other, and the second portion is located on a side of the first portion close to an edge of the flexible printed circuit;
a first conductive film layer located on the first surface of the flexible substrate, where the first conductive film layer includes a first conductive structure attached to the first portion;
a second conductive film layer located on the second surface of the flexible substrate, where the second conductive film layer includes a second conductive structure attached to at least the first portion;
a first cover film located on a side of the first conductive film layer away from the flexible substrate, where along a direction perpendicular to a plane of the flexible printed circuit, the first conductive structure does not overlap with the first cover film; and
a second cover film located on a side of the second conductive film layer away from the flexible substrate, where along the direction perpendicular to the plane of the flexible printed circuit, the second conductive structure does not overlap with the second cover film;
where along the direction perpendicular to the plane of the flexible printed circuit, the first conductive structure overlaps with the second conductive structure, and the first conductive film layer and the second conductive film layer do not overlap with the second portion; and at least a region of the first surface of the second portion close to the edge of the flexible printed circuit is attached to a stiffener structure.

In a second aspect, an embodiment of the present disclosure provides a display module including the flexible printed circuit provided by the first aspect and a display panel, and the flexible printed circuit is electrically connected to the display panel.

In the flexible printed circuit provided by embodiments of the present disclosure, the stiffener structure is provided on a side of the double-sided copper exposure region facing the edge of the flexible printed circuit, so that when performing panelization cutting to obtain the flexible printed circuit, any cutting position has greater thickness and toughness, which in turn can improve the appearance yield and reliability of the flexible printed circuit.

### BRIEF DESCRIPTION OF DRAWINGS

The foregoing aspects and many of the attendant advantages of this invention will become more readily appreciated as the same become better understood by reference to the following detailed description, when taken in conjunction with the accompanying drawings.

FIG. 1 is a schematic diagram of a flexible printed circuit according to an embodiment of the present disclosure;

FIG. 2 is a schematic diagram of another flexible printed circuit according to an embodiment of the present disclosure;

FIG. 3 is a partial schematic diagram of FIG. 1 and FIG. 2, according to an embodiment of the present disclosure;

FIG. 4 is a schematic diagram of a cross-section taken along a direction Al-A2 in FIG. 3, according to an embodiment of the present disclosure;

FIG. 5 is a schematic diagram of a partial cross-section of a flexible printed circuit according to an embodiment of the present disclosure;

FIG. 6 is another partial schematic diagram of FIG. 1 and FIG. 2, according to an embodiment of the present disclosure;

FIG. 7 is a schematic diagram of a cross-section taken along a direction B1-B2 in FIG. 6, according to an embodiment of the present disclosure;

FIG. 8 is a schematic diagram of a partial cross-section of a flexible printed circuit according to an embodiment of the present disclosure;

FIG. 9 is a partial schematic diagram of FIG. 1 and FIG. 2, according to an embodiment of the present disclosure;

FIG. 10 is a schematic diagram of a partial cross-section of another flexible printed circuit according to an embodiment of the present disclosure;

FIG. 11 is another partial schematic diagram of FIG. 1 and FIG. 2, according to an embodiment of the present disclosure;

FIG. 12 is a partially enlarged schematic diagram of FIG. 11, according to an embodiment of the present disclosure;

FIG. 13 is a schematic diagram of a cross-section taken along a line C1-C2 in FIG. 11, according to an embodiment of the present disclosure;

FIG. 14 is a partial schematic diagram of a flexible printed circuit according to an embodiment of the present disclosure;

FIG. 15 is a partial schematic diagram of another flexible printed circuit according to an embodiment of the present disclosure;

FIG. 16 is a partial schematic diagram of another flexible printed circuit according to an embodiment of the present disclosure;

FIG. 17 is a partial schematic diagram of another flexible printed circuit according to an embodiment of the present disclosure;

FIG. 18 is a partial schematic diagram of another flexible printed circuit according to an embodiment of the present disclosure;

FIG. 19 is a partially enlarged schematic diagram of FIG. 18, according to an embodiment of the present disclosure;

FIG. 20 is a schematic diagram of a cross-section taken along a direction D1-D2 in FIG. 18, according to an embodiment of the present disclosure;

FIG. 21 is a schematic diagram of a partial cross-section of another flexible printed circuit according to an embodiment of the present disclosure;

FIG. 22 is a schematic diagram of a cross-section taken along a direction E1-E2 in FIG. 11, according to an embodiment of the present disclosure;

FIG. 23 is a schematic diagram of another cross-section taken along the direction E1-E2 in FIG. 11, according to an embodiment of the present disclosure;

FIG. 24 is a schematic diagram of a partial cross-section of another flexible printed circuit according to an embodiment of the present disclosure;

FIG. 25 is a schematic diagram of a panelization according to an embodiment of the present disclosure;

FIG. 26 is a schematic diagram of a display module according to an embodiment of the present disclosure; and

FIG. 27 is a schematic diagram of a display apparatus according to an embodiment of the present disclosure.

### DESCRIPTION OF EMBODIMENTS

In order to better understand the technical solutions of the present disclosure, embodiments of the present disclosure are described in detail below in conjunction with the drawings.

It should be clear that the described embodiments are merely some of the embodiments of the present disclosure, rather than all of the embodiments. All other embodiments obtained by those of ordinary skill in the art based on the embodiments in present disclosure without creative efforts shall fall within the protection scope of the present disclosure.

The terms used in the embodiments of the present disclosure are merely for the purpose of describing specific embodiments and are not intended to limit present disclosure. The singular forms “a” and “the” used in the embodiments of the present disclosure and the appended claims are also intended to include plural forms, unless the context clearly indicates otherwise.

It should be understood that the term “and/or” used herein is only used to describe the association relationship of associated objects, representing that there can be three relationships. For example, A and/or B can represent: A exists alone, A and B exist at the same time, and B exists alone. In addition, the character “/” herein generally represents that the associated objects before and after it are in an “or” relationship.

In the description of this specification, it should be understood that words such as “basically”, “approximately”, “about”, “approximately”, “roughly”, and “substantially” as described in the claims and embodiments of the present disclosure refer to values that can be substantially accepted within a reasonable process operation range or tolerance range, rather than an exact value.

It should be understood that although terms such as first, second, etc. may be used in the embodiments of the present disclosure to describe transistors, etc., these terms should not be limited to such terms. These terms are only used to distinguish transistors, etc., from each other. For example, without departing from the scope of the embodiments of the present disclosure, a first transistor may also be referred to as a second transistor, and similarly, a second transistor may also be referred to as a first transistor. The applicant of this application provides a solution to the problem existing in the prior art through meticulous and in-depth research.

Flexible printed circuits are also used in the display field. In an application scenario, a flexible printed circuit can connect pins on the front of a display panel to a rigid printed circuit board (PCB) on the back of the display panel, which in turn electrically connects an integrated circuit (IC) attached to the front of the display panel to the rigid PCB on the back of the display panel. In an application scenario, a flexible printed circuit may be provided with an integrated circuit to form a Chip On Flex (COF), where one end of the COF is attached to pins on the front of a display panel, and the other end of the chip on flex is connected to a rigid printed circuit board on the back of the display panel. In addition, a flexible printed circuit can also serve as a circuit board beneath the keys of a display apparatus.

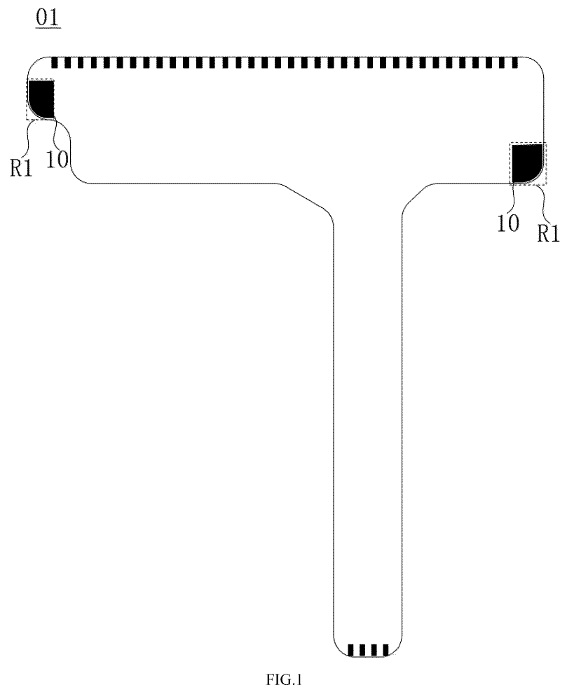

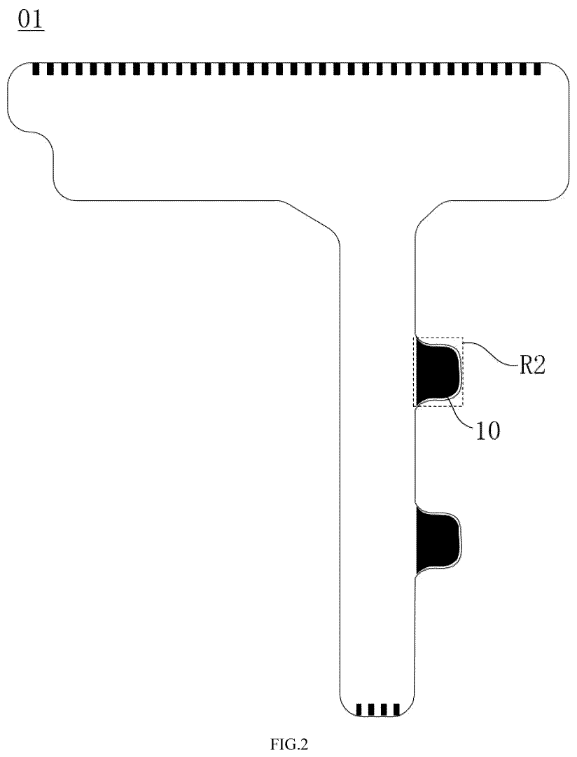

FIG. 1 is a schematic diagram of a flexible printed circuit according to an embodiment of the present disclosure, and FIG. 2 is a schematic diagram of another flexible printed circuit according to an embodiment of the present disclosure.

A flexible printed circuit may include multiple types of copper exposure. For example, pad copper exposure is to achieve soldering with other structures, antenna copper exposure is to reduce radio frequency obstruction for antenna signal transmission and reception, and ground copper exposure is to connect to a ground terminal to discharge static electricity. Due to the space constraints of the flexible printed circuit, at least some copper exposures need to be disposed adjacent to the edge of the flexible printed circuit. Additionally, the regions where the above-mentioned at least some copper exposures are located are double-sided copper exposure regions. For example, as shown in FIG. 1, at least some double-sided copper exposure regions 10 are disposed at corner positions R1 of the flexible printed circuit 01; and if the corner positions R1 of the flexible printed circuit 01 do not have sufficient area to dispose the double-sided copper exposure regions 10, as shown in FIG. 2, irregular regions R2 may be added to the flexible printed circuit 01, and the double-sided copper exposure regions 10 are disposed in the irregular regions R2.

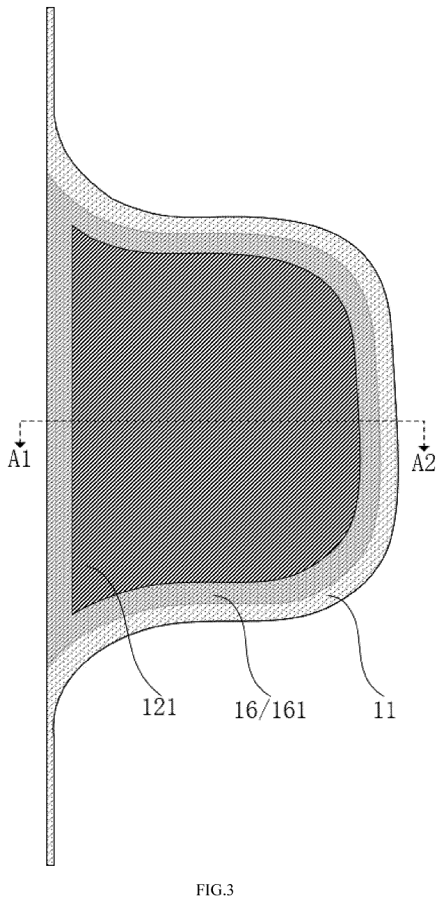

FIG. 3 is a partial schematic diagram of FIG. 1 and FIG. 2, and FIG. 4 is a schematic diagram of a cross-section taken along a direction A1-A2 in FIG. 3.

In the embodiments of the present disclosure, in conjunction with FIG. 3 and FIG. 4, the flexible printed circuit 01 includes a flexible substrate 11, a first conductive film layer 12, a second conductive film layer 13, a first cover film 14, and a second cover film 15. The flexible substrate 11 includes a first surface 1101 and a second surface 1102 opposite to each other. For example, as in a cross-sectional structure shown in FIG. 4, an upper surface of the flexible substrate 11 may be the first surface 1101 and a lower surface of the flexible substrate 11 may be the second surface 1102. The first conductive film layer 12 is located on the first surface 1101 of the flexible substrate 11, and the first cover film 14 is located on a side of the first conductive film layer 12 away from the flexible substrate 11. The second conductive film layer 13 is located on the second surface 1102 of the flexible substrate 11, and the second cover film 15 is located on a side of the second conductive film layer 13 away from the flexible substrate 11. The flexible printed circuit 01 according to the embodiments of the present disclosure is a double-sided board.

In the embodiments of the present disclosure, the flexible substrate 11 may be a polyimide (PI) film or a polyester (PET) film, or may be another specific flexible substrate. The first conductive film layer 12 and the second conductive film layer 13 may be respectively attached to the first surface 1101 and the second surface 1102 of the flexible substrate 11 via adhesive materials. It should be noted that for clear illustration, these adhesive materials are not shown in the drawings provided by the present disclosure.

In addition, in order to improve the conductive performance and corrosion resistance of the flexible printed circuit 01, a surface of the first conductive film layer 12 away from the flexible substrate 11 and a surface of the second conductive film layer 13 away from the flexible substrate 11 may further be gold-plated or immersion-gold-plated. In the embodiments of the present disclosure, the first conductive film layer 12 may include a copper foil disposed on the first surface 1101 of the flexible substrate 11 and metallic gold on the surface thereof, and the second conductive film layer 13 may include a copper foil disposed on the second surface 1102 of the flexible substrate 11 and metallic gold on the surface thereof. In addition, both the first conductive film layer 12 and the second conductive film layer 13 may be copper foils or other metal foils. For clear illustration, the specific compositions of the first conductive film layer 12 and the second conductive film layer 13 are not embodied in the drawings of the embodiments of the present disclosure. Moreover, unless otherwise specified, the first conductive film layer 12 and the second conductive film layer 13 are described by taking copper foils as an example.

The first cover film 14 is located on the surface of the first conductive film layer 12 away from the flexible substrate 11. The first cover film 14 may be attached to the surface of the first conductive film layer 12 away from the flexible substrate 11 for protecting the first conductive film layer 12 from mechanical damage and chemical corrosion. The second cover film 15 is located on the surface of the second conductive film layer 13 away from the flexible substrate 11. The second cover film 15 may be attached to the surface of the second conductive film layer 13 away from the flexible substrate 11 for protecting the second conductive film layer 13 from mechanical damage and chemical corrosion. The first cover film 14 and the second cover film 15 may be PI films or PET films. The first cover film 14 can be attached to the first conductive film layer 12 via an adhesive material, and the second cover film 15 can also be attached to the second conductive film layer 13 via an adhesive material. It can be understood that at least one of the first cover film 14 and the second cover film 15 includes a plurality of hollow portions to expose the conductive film layer, which in turn exposes copper. It should be noted that for clear illustration, these adhesive materials are not shown in the drawings provided by the present disclosure.

The flexible substrate 11 includes a first portion 111 and a second portion 112 connected to each other. The second portion 112 is located on a side of the first portion 111 close to an edge EL of the flexible printed circuit 01. That is, the second portion 112 of the flexible substrate 11 is closer to the edge EL of the flexible printed circuit 01 than the first portion 111. The second portion 112 may be adjacent to the edge EL of the flexible printed circuit 01, and an edge of the second portion 112 away from the first portion 111 may be flush with the edge EL of the flexible printed circuit 01. An area of the flexible substrate 11 may substantially represent an area of the flexible printed circuit 01. The edge EL of the flexible printed circuit 01 is substantially flush with the edge EL of the flexible substrate 11. Since the second portion 112 is located on a side of the first portion 111 close to the edge EL of the flexible printed circuit 01 and the first portion 111 is adjacent to the second portion 112, a distance between the first portion 111 and the edge EL of the flexible printed circuit 01 is smaller and substantially equal to a width of the second portion 112.

Both the first conductive film layer 12 and the second conductive film layer 13 are designed to be recessed relative to the edge of the flexible substrate 11, to minimize the risk of generating conductive burrs in the conductive film layers when performing panelization cutting to obtain the flexible printed circuit 01, such as to minimize the risk of generating copper burrs. Therefore, along a direction perpendicular to a plane of the flexible printed circuit 01, both the first conductive film layer 12 and the second conductive film layer 13 do not overlap with the second portion 112. That is, widths of the first conductive film layer 12 and the second conductive film layer 13 recessed relative to the edge EL of the flexible printed circuit 01 are the width of the second portion 112.

If the edge EL of the flexible printed circuit 01 obtained by panelization cutting has conductive burrs, such as copper burrs, the conductive burrs have a risk of being overlapped and short circuited with other conductive structures. Therefore, the first conductive film layer 12 and the second conductive film layer 13 are designed to be recessed relative to the edge of the flexible substrate 11, which can increase the reliability of the electrical connection of the flexible printed circuit 01. Based on the existing attachment and cutting precision, the width of the first conductive film layer 12 and the second conductive film layer 13 designed to be recessed relative to the edge of the flexible substrate 11 may be about 0.2 mm. That is, a distance between the edges of the first conductive film layer 12 and the second conductive film layer 13 and the edge of the flexible substrate 11 is about 0.2 mm, to avoid cutting the first conductive film layer 12 and the second conductive film layer 13 when performing panelization cutting as much as possible.

The first conductive film layer 12 includes a first conductive structure 121, and the second conductive film layer 13 includes a second conductive structure 131. Along the direction perpendicular to the plane of the flexible printed circuit 01, the first conductive structure 121 overlaps with the second conductive structure 131, the first conductive structure 121 does not overlap with the first cover film 14, and the second conductive structure 131 does not overlap with the second cover film 15. The first conductive structure 121 is a structure of the first conductive film layer 12 that is exposed by the hollow portions of the first cover film 14, and the second conductive structure 131 is a structure of the second conductive film layer 13 that is exposed by the hollow portions of the second cover film 15.

The first conductive structure 121 is attached to the first portion 111, and the second conductive structure 131 is attached to at least the first portion 111. That is, conductive structures exposed by the covering films are provided on both opposite sides of the first portion 111 of the flexible substrate 11. Therefore, a region where the first portion 111 of the flexible printed circuit 01 is located includes a double-sided copper exposure region formed by the first conductive structure 121 and the second conductive structure 131. When the first conductive film layer 12 includes a copper foil and the second conductive film layer 13 includes a copper foil, the first cover film 14 exposes the first conductive structure 121 to form a copper exposure, and the second cover film 15 exposes the second conductive structure 131 to form a copper exposure, and thus the region where the first conductive structure 121 is located may be a double-sided copper exposure region. The region where the first portion 111 of the flexible substrate 11 is located may be a double-sided copper exposure region. Copper foils exposed by the cover films are attached to both opposite sides of the flexible substrate 11 in the double-sided copper exposure region.

The first conductive structure 121 is attached to the first portion 111, and thus a first surface of the second portion 112 is not attached to the first conductive structure 121. Since the second portion 112 is adjacent to the edge EL of the flexible printed circuit 01 and the second portion 112 is not attached to the first conductive film layer 12 and the second conductive film layer 13, in order to increase the space utilization rate of the flexible printed circuit 01, the width of the second portion 112 is narrower, and thus the distance between the first portion 111 and the edge EL of the flexible printed circuit 01 is short. Therefore, when both the first conductive film layer 12 and the second conductive film layer 13 include copper foils, a distance between the double-sided copper exposure region included in the region where the first portion 111 is located and the edge EL of the flexible printed circuit 01 is short.

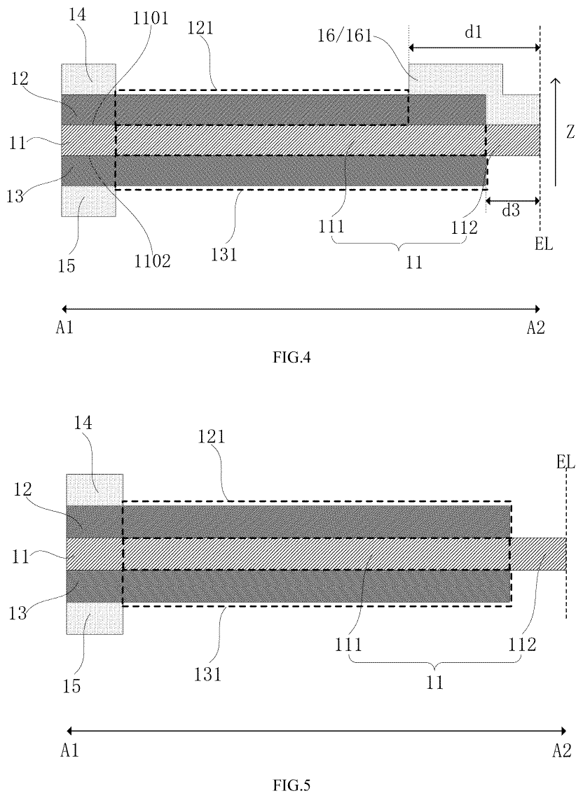

FIG. 5 is a schematic diagram of a partial cross-section of a flexible printed circuit related to an embodiment of the present disclosure.

As shown in FIG. 5, since the double-sided copper exposure region including the first conductive structure 121 and the second conductive structure 131 is close to the edge EL of the flexible printed circuit 01, after the hollow portion exposing the first conductive structure 121 is provided on the first cover film 14, the hollow portion may simultaneously expose the first conductive structure 121 and a region of the second portion 112 located on a side of the first conductive structure 121 adjacent to the edge EL of the flexible printed circuit 01. Therefore, after the first cover film 14 is attached to the first conductive film layer 12, the hollow portion exposing the first conductive structure 121 can extend to the edge EL of the flexible printed circuit 01 along a direction parallel to the plane of the flexible printed circuit 01; and after the hollow portion exposing the second conductive structure 131 is provided on the second cover film 15, the hollow portion may simultaneously expose the second conductive structure 131 and a region of the second portion 112 located on a side of the second conductive structure 131 adjacent to the edge EL of the flexible printed circuit 01. Therefore, after the second cover film 15 is attached to the second conductive film layer 13, the hollow portion exposing the second conductive structure 131 can extend to the edge EL of the flexible printed circuit 01 along the direction parallel to the plane of the flexible printed circuit 01. Such a fabrication of the flexible printed circuit 01 reduces the difficulty of providing the hollow portions on the cover films. However, the flexible printed circuit 01 shown in FIG. 5 is prone to poor appearance such as hairline cracks, damage, and missing parts.

As described above, as shown in FIG. 5, at least a partial region of the second portion 112 is not attached to the first conductive film layer 12, the second conductive film layer 13, the first cover film 14, and the second cover film 15, so that an overall thickness of the flexible printed circuit 01 in the partial region where the second portion 112 is located is thinner. For example, in the region where the second portion 112 is located as shown in FIG. 5, the overall thickness of the flexible printed circuit 01 is substantially a thickness of the flexible substrate 11 and is usually about 25 μm. This results in the situation that when performing panelization cutting to obtain the flexible printed circuit 01, the thickness at some cutting positions is thinner and the texture is more brittle. As a result, due to the impact of punching, poor appearance such as hairline cracks, damage, and missing parts is likely to occur.

In the embodiments of the present disclosure, as shown in FIG. 3 and FIG. 4, the flexible printed circuit 01 further includes a stiffener structure 16. At least a region of the first surface 1101 of the second portion 112 close to the edge EL of the flexible printed circuit 01 is attached to the stiffener structure 16. That is, the flexible substrate 11 has the stiffener structure 16 in a region close to the edge. Therefore, the flexible printed circuit 01 has the stiffener structure 16 on a side of the double-sided copper exposure region facing the edge EL of the flexible printed circuit 01, so that when performing panelization cutting to obtain the flexible printed circuit 01, any cutting position has a greater thickness and toughness, which in turn can improve the appearance yield and reliability of the flexible printed circuit 01.

In an embodiment of the present disclosure, as shown in FIG. 4, the stiffener structure 16 at least includes a first stiffener structure 161. The first stiffener structure 161 and the first cover film 14 are located in a same film layer. Therefore, the first stiffener structure 161 is at least located on a side of the first conductive structure 121 facing the edge EL of the flexible printed circuit 01. A portion of the flexible substrate 11 located on a side of the double-sided copper exposure region close to the edge EL of the flexible printed circuit 01 is attached to the first stiffener structure 161, and the first stiffener structure 161 can be fabricated simultaneously with the first cover film 14, which can reduce the fabrication difficulty of the flexible printed circuit 01 and thus reduce the cost.

In some implementations, the first stiffener structure 161 and the first cover film 14 are formed as an integral structure. That is, the first stiffener structure 161 and the first cover film 14 belong to a continuous structure. The first cover film 14 and the first stiffener structure 161 can be regarded as different portions of the cover film located on the side of the first surface 1101 of the flexible substrate 11, where the first stiffener structure 161 is a portion of the cover film located on the side of the first conductive structure 121 facing the edge EL of the flexible printed circuit 01 and attached to at least the second portion 112. The hollow portion on the first cover film 14 may be provided before the first cover film 14 is attached to the first conductive film layer 12, and thus, after providing the hollow portion exposing the first conductive structure 121, the first stiffener structure 161 is also formed.

In an embodiment of the present disclosure, as shown in FIG. 4, a minimum distance between the first conductive structure 121 and the edge EL of the flexible printed circuit 01 is d1, where d1 is greater than or equal to 0.5 mm. Since the first conductive structure 121 is exposed by the first cover film 14 located on the side of the first surface 1101 of the flexible substrate 11, a minimum distance between an edge of the hollow portion exposing the first conductive structure 121 and the edge EL of the flexible printed circuit 01 is greater than or equal to 0.5 mm. When the first stiffener structure 161 and the first cover film 14 are located in the same layer, a minimum distance between an edge of the first stiffener structure 161 adjacent to the hollow portion and the edge EL of the flexible printed circuit 01 is d1, where d1 is greater than or equal to 0.5 mm. That is, a width of the first stiffener structure 161 is substantially d1, where d1 is greater than or equal to 0.5 mm.

In the flexible printed circuit 01 according to this embodiment, when the first cover film 14 is attached to the first conductive film layer 12, a certain misalignment exists in the alignment between the hollow portion needing to expose the first conductive structure 121 and the first conductive structure 121 due to process errors. That is, even if a certain misalignment exists in the alignment between the first stiffener structure 161 outside the hollow portion and the second portion 112 due to process errors, since the width of the first stiffener structure 161 is set to be greater than or equal to 0.5 mm and the existing attachment precision is less than 0.5 mm, the first stiffener structure 161 and the second portion 112 can be attached to each other as long as the distance of the attachment misalignment does not exceed 0.5 mm. Therefore, the risk that the first stiffener structure 161 is attached to the outside of the region where the flexible printed circuit 01 is located with a deviation is greatly reduced. That is, the risk that the second portion 112 cannot be attached to the first stiffener structure 161 is also greatly reduced.

In an embodiment of the present disclosure, as shown in FIG. 4, the stiffener structure 16 is not positioned between the second conductive structure 131 and the edge EL of the flexible printed circuit 01 that is adjacent to the second conductive structure 131. That is, the stiffener structure 16 is not disposed on the second surface 1102 of the second portion 112 on a side of the second conductive structure 131 facing the edge EL of the flexible printed circuit 01.

As shown in FIG. 4, the minimum distance between the first conductive structure 121 and the edge EL of the flexible printed circuit 01 is greater than a minimum distance between the second conductive structure 131 and the edge EL of the flexible printed circuit 01. An edge of the second conductive structure 131 facing the edge EL of the flexible printed circuit 01 is a part of the edge of the second conductive film layer 13 facing the flexible printed circuit 01, so that the area of the second conductive structure 131 is relatively larger, the manufacturing difficulty thereof is low and the yield of the electrical connection with an external device is increased.

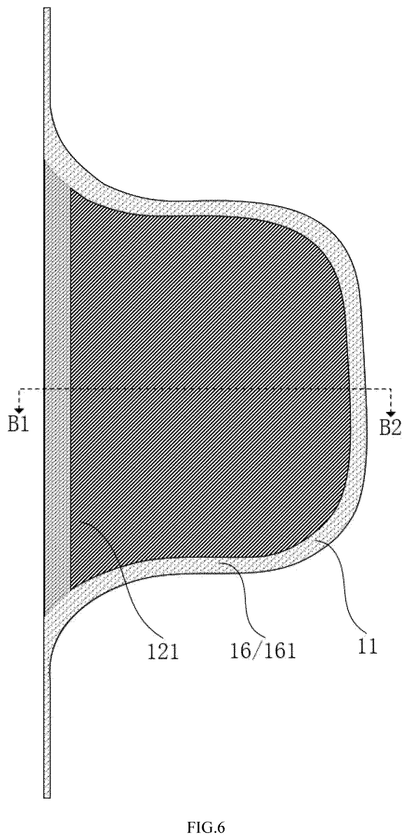

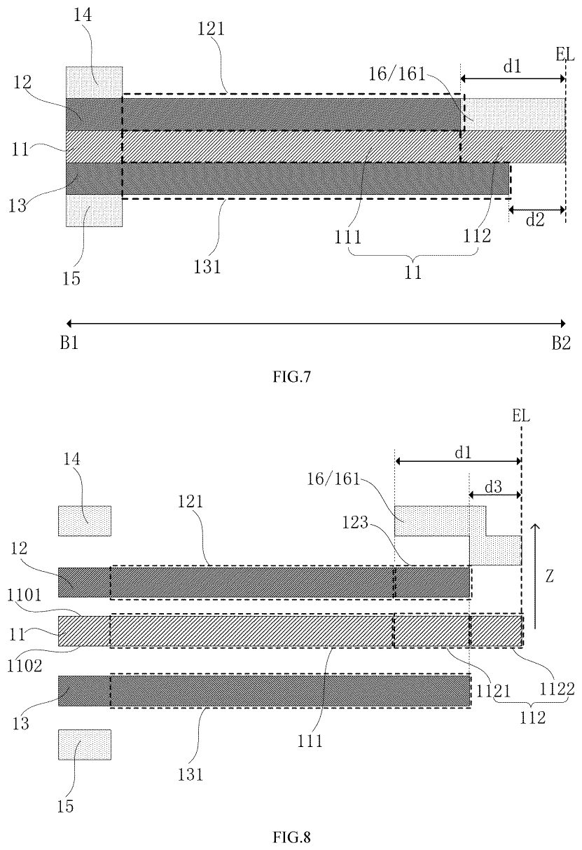

FIG. 6 is another partial schematic diagram of FIG. 1 and FIG. 2, and FIG. 7 is a schematic diagram of a cross-section taken along a direction B1-B2 in FIG. 6.

In an embodiment of the present disclosure, as shown in FIG. 6 and FIG. 7, the first stiffener structure 161 is attached to the second portion 112. That is, the first stiffener structure 161 is not attached to the first conductive film layer 12, where the width of the first conductive film layer 12 recessed relative to the edge EL of the flexible printed circuit 01 may be 0.2 mm or 0.5 mm.

In a technical solution corresponding to this embodiment, as shown in FIG. 7, the stiffener structure 16 is not positioned between the second conductive structure 131 and the edge EL of the flexible printed circuit 01 that is adjacent to the second conductive structure 131, and the first stiffener structure 161 is not attached to the first conductive film layer 12. In this case, the width of the first conductive film layer 12 recessed relative to the edge EL of the flexible printed circuit 01 is greater than the width of the second conductive film layer 13 recessed relative to the edge EL of the flexible printed circuit 01, so that a distance between the first conductive structure 121 and the edge EL of the flexible printed circuit 01 is greater than a distance between the second conductive structure 131 and the edge EL of the flexible printed circuit 01. For example, the width of the first conductive film layer 12 recessed relative to the edge EL of the flexible printed circuit 01 is d1 and d1=0.5 mm. The width of the second conductive film layer 13 recessed relative to the edge EL of the flexible printed circuit 01 is d2 and d2=0.2 mm. When the width of the first conductive film layer 12 recessed relative to the edge EL of the flexible printed circuit 01 is larger, the first stiffener structure 161 can have a larger width to reduce the manufacturing difficulty of the first stiffener structure 161, and the difficulty of attaching the second portion 112 of the flexible substrate 11 to the first stiffener structure 161 is reduced.

FIG. 8 is a schematic diagram of a partial cross-section of a flexible printed circuit according to an embodiment of the present disclosure. It should be noted that in order to more clearly illustrate different structures of the flexible printed circuit 01, FIG. 8 separates the structures in the flexible printed circuit 01 sequentially arranged along the direction Z perpendicular to the plane of the flexible printed circuit 01, and when these structures are attached together, they appear as shown in FIG. 4.

In an embodiment of the present disclosure, as shown in FIG. 8, the second portion 112 includes a first sub-portion 1121 and a second sub-portion 1122. The second sub-portion 1122 is located on a side of the first sub-portion 1121 close to the edge EL of the flexible printed circuit 01. The first conductive film layer 12 includes a third conductive structure 123 connected to the first conductive structure 121, and the third conductive structure 123 is attached to the first sub-portion 1121. Since the first conductive structure 121 is attached to the first portion 111 and the first sub-portion 1121 is located on the side of the first portion 111 close to the edge EL of the flexible printed circuit 01, the third conductive structure 123 attached to the first sub-portion 1121 is located on a side of the first conductive structure 121 attached to the first portion 111 close to the edge EL of the flexible printed circuit 01. That is, the first conductive film layer 12 extends along a direction from the first conductive structure 121 towards the edge EL of the flexible printed circuit 01 and forms the third conductive structure 123.

In this embodiment, the first conductive film layer 12 is not attached to the second sub-portion 1122, to realize the retraction of the first conductive film layer 12 relative to the edge EL of the flexible printed circuit 01. A portion of the first stiffener structure 161 is attached to the third conductive structure 123, and another portion of the first stiffener structure 161 is attached to the first surface 1101 of the second sub-portion 1122. That is, the first stiffener structure 161 is attached to an edge portion of the first conductive film layer 12 included on a side of the first conductive structure 121 facing the flexible printed circuit 01 and the flexible substrate 11 that is not attached by the first conductive film layer 12. Therefore, the first stiffener structure 161 can have a wider width, thereby reducing the manufacturing difficulty.

In a technical solution corresponding to this embodiment, as shown in FIG. 4 and FIG. 8, the stiffener structure 16 is not positioned between the second conductive structure 131 and the edge EL of the flexible printed circuit 01 that is adjacent to the second conductive structure 131, and a portion of the first stiffener structure 161 is attached to the third conductive structure 123, where the widths of the first conductive film layer 12 and the second conductive film layer 13 recessed relative to the edge EL of the flexible printed circuit 01 can be the same. Therefore, the first stiffener structure 161 is attached to at least a portion of an edge region of the first conductive film layer 12, so that a distance between the first conductive structure 121 exposed by the hollow portion of the first cover film 14 and the edge EL of the flexible printed circuit 01 is greater than the width of the first conductive film layer 12 recessed relative to the edge EL of the flexible printed circuit 01; and the orthographic projection of the edge of the second conductive structure 131 facing the edge EL of the flexible printed circuit 01 onto the flexible substrate 11 is located between the orthographic projection of the edge of the first conductive film layer 12 facing the edge EL of the flexible printed circuit 01 onto the flexible substrate 11 and the edge EL. For example, as shown in FIG. 8, the widths of the first conductive film layer 12 and the second conductive film layer 13 recessed relative to the edge EL of the flexible printed circuit 01 are both d3 and d3=0.2 mm, and the distance between the first conductive structure 121 and the edge EL of the flexible printed circuit 01 is d1 and d1=0.5 mm. When widths of the first conductive film layer 12 and the second conductive film layer 13 recessed relative to the edge EL of the flexible printed circuit 01 are the same, the manufacturing difficulty of the flexible printed circuit 01 can be reduced and the effective utilization rate of the first conductive film layer 12 and the second conductive film layer 13 can be made higher. In addition, when the width between the first conductive structure 121 and the edge EL of the flexible printed circuit 01 is larger, the first stiffener structure 161 can have a larger width to reduce the manufacturing difficulty thereof, and the difficulty of attaching the first stiffener structure 161 is reduced.

As shown in FIG. 4 and FIG. 8, when a region between the second conductive structure 131 and the edge EL of the adjacent flexible printed circuit 01 does not include the stiffener structure 16, an edge of the third conductive structure 123 close to the edge EL of the flexible printed circuit 01 is aligned, along the direction perpendicular to the plane of the flexible printed circuit 01, with an edge of the second conductive structure 131 close to the edge EL of the flexible printed circuit 01. Therefore, a part of the second conductive structure 131 is attached to the second surface of the first portion 111 of the flexible substrate 11, and another part of the second conductive structure 131 is attached to the second surface of the first sub-portion 1121. The first conductive structure 121 is attached to the first surface of the first portion 111 of the flexible substrate 11, and the third conductive structure 123 is attached to the first surface of the first sub-portion 1121 of the flexible substrate 11. Neither the first surface nor the second surface of the second sub-portion 1122 of the flexible substrate 11 is attached to the conductive film layers. For example, as shown in FIG. 8, a right edge of the third conductive structure 123 is its edge close to the edge EL of the flexible printed circuit 01, a right edge of the second conductive structure 131 is its edge close to the edge EL of the flexible printed circuit 01, and the right edge of the third conductive structure 123 is aligned, along the direction perpendicular to the plane of the flexible printed circuit, with the right edge of the second conductive structure 131. In this technical solution, the width of the first conductive film layer 12 recessed relative to the edge EL of the flexible printed circuit 01 is equal to the width of the second conductive film layer 13 recessed relative to the flexible printed circuit 01, thereby reducing the manufacturing difficulty of the first conductive film layer 12 and the second conductive film layer 13.

FIG. 9 is a partial schematic diagram of FIG. 1 and FIG. 2.

In an embodiment of the present disclosure, as shown in FIG. 9, the stiffener structure 16 includes a second stiffener structure 162, and at least a portion of the second surface 1102 of the second portion 112 close to the edge EL of the flexible printed circuit 01 is attached to the second stiffener structure 162. The second stiffener structure 162 is at least located on the side of the second conductive structure 131 facing the edge EL of the flexible printed circuit 01. Both the first surface 1101 and the second surface 1102 of the second portion 112 are attached to the stiffener structure 16. Therefore, a portion of the flexible substrate 11 located on the side of the double-sided copper exposure region close to the edge EL of the flexible printed circuit 01 is attached to the first stiffener structure 161 and the second stiffener structure 162.

The flexible printed circuit 01 according to this embodiment includes the first stiffener structure 161 and the second stiffener structure 162 on the side of the double-sided copper exposure region facing the edge EL of the flexible printed circuit 01. Therefore, a portion of the flexible printed circuit 01 located on the side of the double-sided copper exposure region facing the edge EL of the flexible printed circuit 01 has greater thickness and toughness, effectively reducing the probability of poor appearance including burrs, cracks, and material loss when performing panelization cutting to obtain the flexible printed circuit 01.

In an embodiment of the present disclosure, as shown in FIG. 9, the second stiffener structure 162 and the second cover film 15 are located in a same film layer, and thus the second stiffener structure 162 and the second cover film 15 can be fabricated simultaneously, which can reduce the manufacturing difficulty of the flexible printed circuit 01 and thus reduce the cost.

In some implementations, the second stiffener structure 162 and the second cover film 15 are formed as an integral structure. That is, the second stiffener structure 162 and the second cover film 15 belong to a continuous structure. The second cover film 15 and the second stiffener structure 162 can be regarded as different portions of the cover film located on the side of the second surface 1102 of the flexible substrate 11, where the second stiffener structure 162 is a portion of the cover film located on the side of the second conductive structure 131 facing the edge EL of the flexible printed circuit 01 and attached to at least the second portion 112. The hollow portion on the second cover film 15 may be provided before the second cover film 15 is attached to the second conductive film layer 13. Therefore, after providing the hollow portion exposing the second conductive structure 131, the second stiffener structure 162 is also formed.

In an embodiment of the present disclosure, as shown in FIG. 9, the minimum distance between the second conductive structure 131 and the edge EL of the flexible printed circuit 01 is greater than or equal to 0.5 mm. Since the second conductive structure 131 is exposed by the second cover film 15 located on the side of the first surface 1101 of the flexible substrate 11, a minimum distance between an edge of the hollow portion exposing the second conductive structure 131 and the edge EL of the flexible printed circuit 01 is greater than or equal to 0.5 mm. When the second stiffener structure 162 and the second cover film 15 are located in the same layer, a minimum distance between an edge of the second stiffener structure 162 adjacent to the hollow portion and the edge EL of the flexible printed circuit 01 is d4, where d4 is greater than or equal to 0.5 mm. That is, a width of the second stiffener structure 162 is substantially d4, where d4 is greater than or equal to 0.5 mm.

In the flexible printed circuit 01 according to this embodiment, when the second cover film 15 is attached to the second conductive film layer 13, a certain misalignment exists in the alignment between the hollow portion needing to expose the second conductive structure 131 and the second conductive structure 131 due to process errors. That is, even if a certain misalignment exists in the alignment between the second stiffener structure 162 outside the hollow portion and the second portion 112 due to process errors, since the width of the second stiffener structure 162 is set to be greater than or equal to 0.5 mm and the existing attachment precision is less than 0.5 mm, the second stiffener structure 162 and the second portion 112 can be attached to each other as long as the distance of the attachment misalignment does not exceed 0.5 mm. Therefore, the risk that the second stiffener structure 162 is attached to the outside of the region where the flexible printed circuit 01 is located with a deviation is greatly reduced. That is, the risk that the second portion 112 cannot be attached to the second stiffener structure 162 is also greatly reduced.

In a feasible implementation, as shown in FIG. 9, the second conductive film layer 13 includes a fourth conductive structure 133 connected to the second conductive structure 131. The fourth conductive structure 133 is attached to the first sub-portion 1121, and the second conductive film layer 13 is not attached to the second sub-portion 1122. In this case, the fourth conductive structure 133 may share the same inventive concept as the third conductive structure 123 in the above-described embodiment, and thus details thereof are not described herein again.

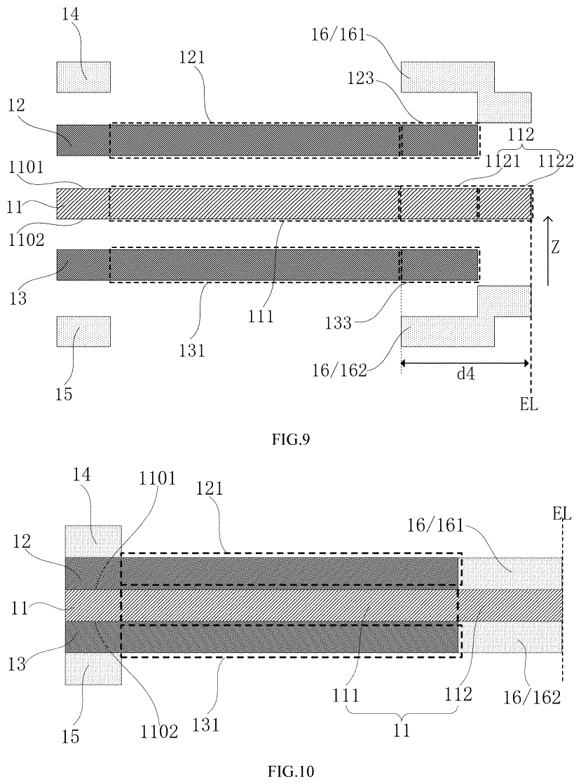

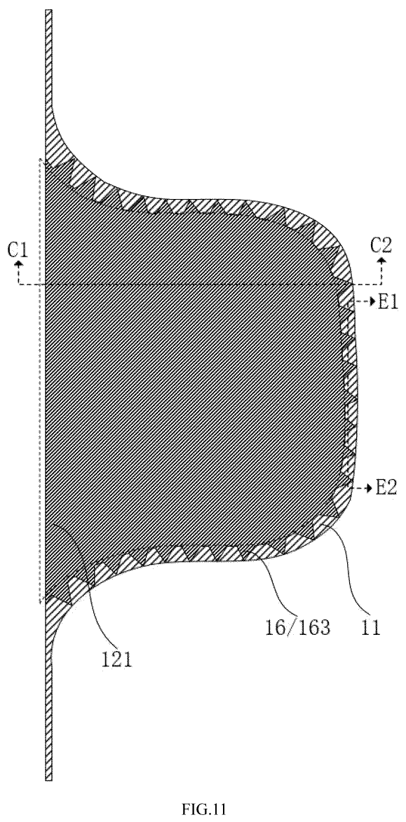

FIG. 10 is a schematic diagram of a partial cross-section of another flexible printed circuit according to an embodiment of the present disclosure.

In a feasible implementation, as shown in FIG. 10, the second stiffener structure 162 is attached to the second portion 112. That is, the second stiffener structure 162 is not attached to the second conductive film layer 13. In this case, the second stiffener structure 162 and the second conductive structure 131 may share the same inventive concept as the first stiffener structure 161 and the first conductive structure 121 in the embodiments corresponding to FIG. 6 and FIG. 7, and details thereof are not described herein again.

In an embodiment of the present disclosure, as shown in FIG. 9 and FIG. 10, an edge of the first conductive structure 121 close to the edge EL of the flexible printed circuit 01 is aligned, along the direction perpendicular to the plane of the flexible printed circuit 01, with the edge of the second conductive structure 131 close to the edge EL of the flexible printed circuit 01. For example, as shown in FIG. 9 and FIG. 10, a right edge of the first conductive structure 121 is its edge close to the edge EL of the flexible printed circuit 01, and the right edge of the second conductive structure 131 is its edge close to the edge EL of the flexible printed circuit 01. The right edge of the first conductive structure 121 is aligned, along the direction Z perpendicular to the plane of the flexible printed circuit 01, with the right edge of the second conductive structure 131.

In a technical solution corresponding to this embodiment, an area of the first conductive structure 121 in a plane parallel to the flexible printed circuit 01 is equal to an area of the second conductive structure 131 in the plane parallel to the flexible printed circuit 01, and thus an orthographic projection of the first conductive structure 121 onto the flexible substrate 11 may coincide with an orthographic projection of the second conductive structure 131 onto the flexible substrate 11. At this case, the process schemes and process precision for fabricating the first conductive structure 121 and the second conductive structure 131 may be the same, which is easy to implement.

For example, as shown in FIG. 9, a portion of the first stiffener structure 161 is attached to the first conductive film layer 12, and a portion of the second stiffener structure 162 is attached to the second conductive film layer 13. Along the direction Z perpendicular to the plane of the flexible printed circuit 01, the projection of the first conductive structure 121 onto the flexible substrate 11 coincide with the projection of the second conductive structure 131 onto the flexible substrate 11.

For example, as shown in FIG. 10, the first stiffener structure 161 is not attached to the first conductive film layer 12, and the second stiffener structure 162 is not attached to the second conductive film layer 13. Along the direction Z perpendicular to the plane of the flexible printed circuit 01, the projection of the first conductive structure 121 onto the flexible substrate 11 coincide with the projection of the second conductive structure 131 onto the flexible substrate 11.

It should be noted that the foregoing projection coincidence refers to projection coincidence within a range of process error.

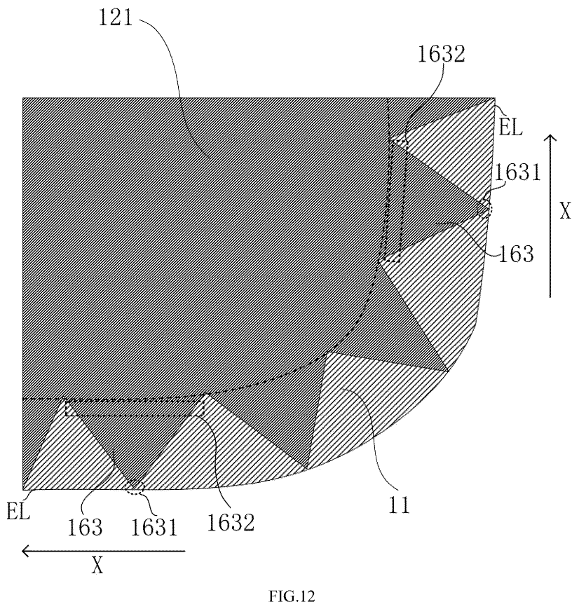

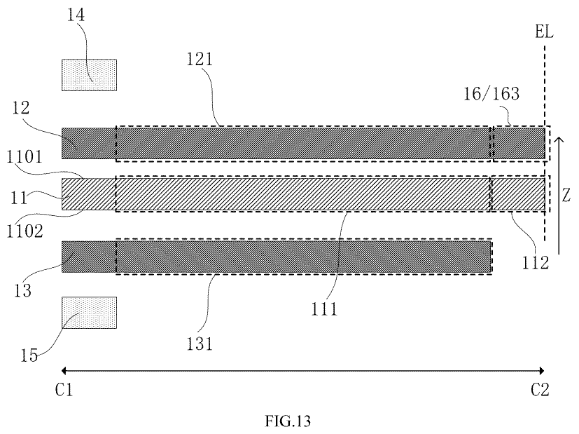

FIG. 11 is another partial schematic diagram of FIG. 1 and FIG. 2, FIG. 12 is a partially enlarged schematic diagram of FIG. 11, and FIG. 13 is a schematic diagram of a cross-section taken along a line C1-C2 in FIG. 11.

In an embodiment of the present disclosure, in conjunction with FIG. 11, FIG. 12, and FIG. 13, the stiffener structure 16 includes a plurality of third stiffener structures 163. The third stiffener structures 163 and the first conductive film layer 12 are located in a same film layer. Therefore, the third stiffener structure 163 and the first conductive film layer 12 can be fabricated simultaneously, so that the flexible printed circuit 01 has a simple fabrication process flow.

The third stiffener structures 163 are at least located on the side of the first conductive structure 121 facing the edge EL of the flexible printed circuit 01. The third stiffener structures 163 include first end portions 1631 adjacent to the edge EL of the flexible printed circuit 01 and first connecting portions 1632 away from the edge of the flexible printed circuit 01 and connected to the first conductive structure 121. Therefore, the plurality of third stiffener structures 163 can be regarded as protrusions disposed on the side of the first conductive structure 121 facing the edge EL of the flexible printed circuit 01 and connected to the first conductive structure 121. For example, as shown in FIG. 11, multiple third stiffener structures 163 are included between the first conductive structure 121 and the edge EL located above the first conductive structure 121, multiple third stiffener structures 163 are included between the first conductive structure 121 and the edge EL located below the first conductive structure 121, and multiple third stiffener structures 163 are included between the first conductive structure 121 and the edge EL located to the right of the first conductive structure 121.

In addition, a width of the first end portion 1631 of the third stiffener structure 163 along a first direction X may be smaller than a width of the first connecting portion 1632 along the first direction X, where the first direction X is parallel to an extending direction of the edge of the flexible printed circuit 01 adjacent to the first end portion 1631. That is, a width of an end of the third stiffener structure 163 adjacent to the edge of the flexible printed circuit 01 is smaller than a width of an end of the third stiffener structure 163 away from the edge of the flexible printed circuit 01. For example, as shown in FIG. 12, a lower end of the third stiffener structure 163 between the first conductive structure 121 and the edge EL below the first conductive structure 121 is the first end portion 1631, and an upper end of the third stiffener structure 163 is the first connecting portion 1632. In this case, the first direction X is parallel to the extending direction of the edge EL, and the first direction X is a row direction. Therefore, a width of the first end portion 1631 along the row direction is smaller than a width of the first connecting portion 1632 along the row direction. A right end of the third stiffener structure 163 between the first conductive structure 121 and the edge EL located to the right of the first conductive structure 121 is the first end portion 1631, and a left end of the third stiffener structure 163 is the first connecting portion 1632. In this case, the first direction X is parallel to the extending direction of the edge EL, and the first direction X is a column direction. Therefore, a width of the first end portion 1631 along the column direction is smaller than a width of the first connecting portion 1632 along the column direction. In conjunction with FIG. 11 and FIG. 12, an upper end of the third stiffener structure 163 between the first conductive structure 121 and the edge EL above the first conductive structure 121 is the first end portion 1631, and a lower end of the third stiffener structure 163 is the first connecting portion 1632. In this case, the first direction X is parallel to the extending direction of the edge EL, and the first direction X is the row direction. Therefore, the width of the first end portion 1631 along the row direction is smaller than the width of the first connecting portion 1632 along the row direction. It should be noted that the first direction X does not point to a single unique direction; instead, it can represent the extending direction of an edge EL of the flexible printed circuit 01. Since the extending direction of the edge EL of the flexible printed circuit 01 varies in different regions, the pointing directions of the first direction X corresponding to those regions are also different.

In this embodiment, the third stiffener structures 163 are attached to the second portion 112 of the flexible substrate 11. That is, the portion of the flexible substrate 11 located on the side of the double-sided copper exposure region close to the edge EL of the flexible printed circuit 01 is attached to the third stiffener structures 163, and the third stiffener structures 163 can be fabricated simultaneously with the first conductive film layer 12, which can reduce the fabrication difficulty of the flexible printed circuit 01 and reduce the cost. In addition, the first end portions 1631 of the third stiffener structures 163 in the same layer as the first conductive film layer 12 have a smaller width. Therefore, the provision of the third stiffener structures 163 improve the thickness and toughness of the cutting position while reducing the probability of conductive burrs occurring in the third stiffener structures 163, thereby ensuring the reliability of the flexible printed circuit 01.

In an embodiment of the present disclosure, as shown in FIG. 11, the third stiffener structures 163 and the first conductive structure 121 are formed as an integral structure. That is, the third stiffener structures 163 and the first conductive structure 121 belong to a continuous structure. The third stiffener structures 163 and the first conductive structure 121 can be regarded as different portions of the conductive film layer located on the side of the first surface 1101 of the flexible substrate 11, where the third stiffener structures 163 are portions of the conductive film layer located on the side of the first conductive structure 121 facing the edge EL of the flexible printed circuit 01 and attached to at least the second portion 112. While the conductive film layer is patterned to obtain lines and conductive structures, including the first conductive structure 121, the third stiffener structures 163 can be obtained simultaneously.

In an embodiment of the present disclosure, the third stiffener structures 163 includes a copper film. In particular, the third stiffener structures 163 may be a portion of a copper film coated or deposited on the first surface 1101 of the flexible substrate 11, or may be a portion of a copper film formed after a copper foil is attached to the first surface 1101 of the flexible substrate 11.

When the third stiffener structures 163 and the first conductive film layer 12 are located in the same film layer, the first conductive film layer 12 may also include the above-mentioned copper film.

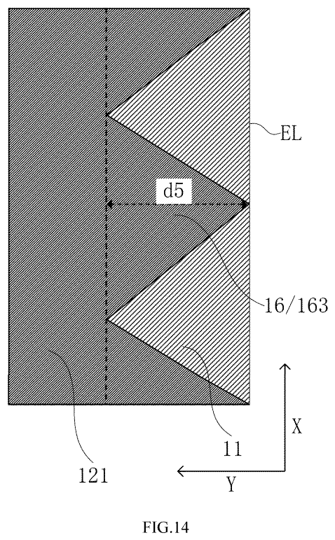

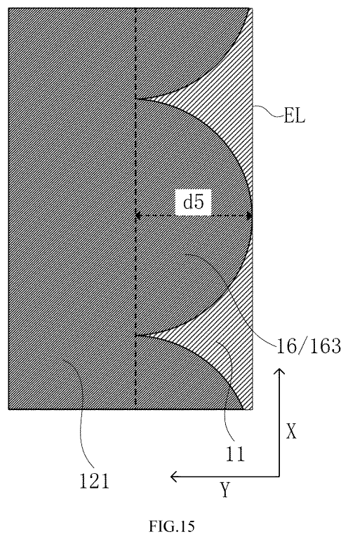

FIG. 14 is a partial schematic diagram of a flexible printed circuit according to an embodiment of the present disclosure, FIG. 15 is a partial schematic diagram of another flexible printed circuit according to an embodiment of the present disclosure, and FIG. 16 is a partial schematic diagram of another flexible printed circuit according to an embodiment of the present disclosure.

As shown in FIG. 14 to FIG. 16, a shape of the third stiffener structure 163 includes at least one of a triangle, a semi-circle, or a trapezoid, where the shape of the third stiffener structure 163 is a shape of the third stiffener structure 163 in the plane parallel to the flexible printed circuit 01, that is, a shape of an orthographic projection of the third stiffener structure onto the flexible substrate 11.

For example, as shown in FIG. 14, the shape of the third stiffener structure 163 is a triangle, and one vertex angle of the triangle is adjacent to or coincides with the edge EL of the flexible printed circuit 01, and the other two vertex angles are away from the edge EL of the flexible printed circuit 01. For example, as shown in FIG. 15, the shape of the third stiffener structure 163 is a semi-circle. An arc-shaped edge of the semi-circle is adjacent to or partially overlapped with the edge of the flexible printed circuit 01, and a straight edge is away from the edge EL of the flexible printed circuit 01. For example, as shown in FIG. 16, the shape of the third stiffener structure 163 is a trapezoid, and a bottom edge with a shorter length of the trapezoid is adjacent to or coincides with the edge EL of the flexible printed circuit 01, and a bottom edge with a longer length is away from the edge EL of the flexible printed circuit 01.

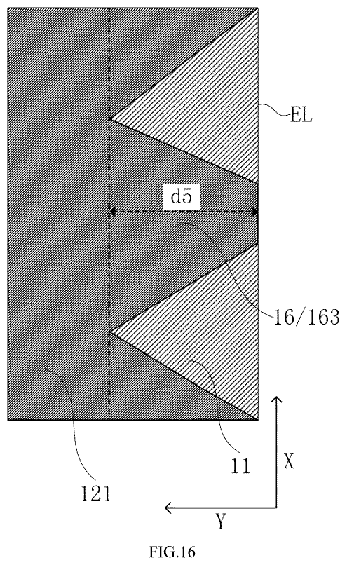

FIG. 17 is a partial schematic diagram of another flexible printed circuit according to an embodiment of the present disclosure.

In an embodiment of the present disclosure, as shown in FIG. 17, the stiffener structure 16 includes both the first stiffener structure 161 and the third stiffener structures 163. That is, the side of the first surface 1101 of the second portion 112 of the flexible substrate 11 includes the first stiffener structure 161 and the third stiffener structures 163. In the flexible printed circuit 01 according to this embodiment, the side of the first conductive structure 121 facing the edge EL of the flexible printed circuit 01 includes the third stiffener structures 163 and the first stiffener structure 161 that are stacked. Therefore, when performing panelization cutting to obtain the flexible printed circuit 01, any cutting position has a greater thickness and toughness, which in turn can improve the appearance yield and reliability of the flexible printed circuit 01.

It should be noted that FIG. 17 illustrates an attachment that the first stiffener structure 161 is attached to the second sub-portion 1122 and the third conductive structures 123 of the first conductive film layer 12, while the first stiffener structure 161 may also be attached to the second portion 112 and not be attached to the first conductive film layer 12.

In an embodiment of the present disclosure, as shown in FIG. 14 to FIG. 16, a length of the third stiffener structure 163 along a second direction is d5, where d5 is greater than or equal to 0.2 mm. The second direction Y is parallel to an arrangement direction of the second portion 112 to which the third stiffener structure 163 attached and the first portion 111 connected thereto. In addition, the second direction Y can also be perpendicular to the extending direction X of the edge EL of the flexible printed circuit 01 adjacent to the third stiffener structure 163.

When the length of the third stiffener structure 163 along the second direction is greater than or equal to 0.2 mm, it can be ensured that the third stiffener structure 163 is provided at the cutting position and the second conductive film layer 13 is effectively prevented from being cut when the error of panelization cutting is considered. In addition, the third stiffener structure 163 is easier to fabricate.

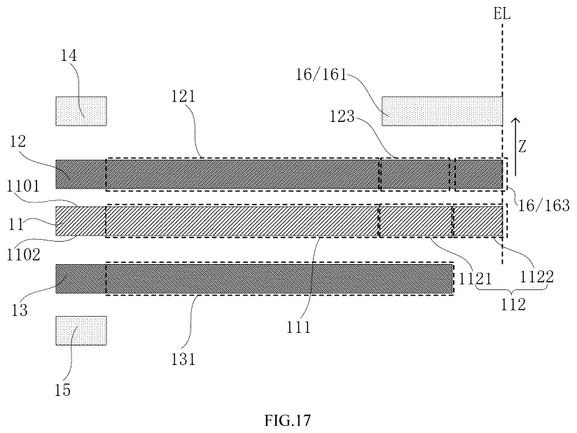

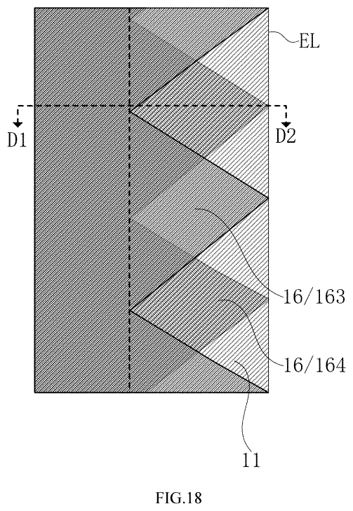

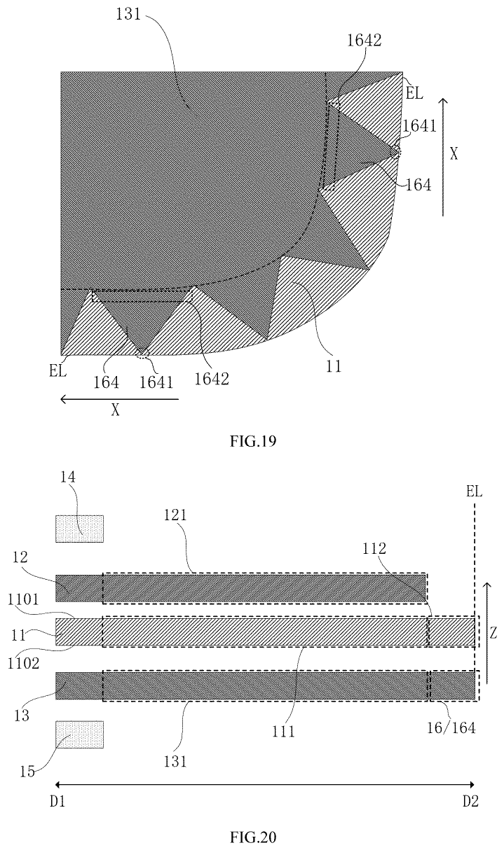

FIG. 18 is a partial schematic diagram of another flexible printed circuit according to an embodiment of the present disclosure, and FIG. 19 is a partially enlarged schematic diagram of FIG. 18, and FIG. 20 is a schematic diagram of a cross-section taken along a direction D1-D2 in FIG. 18.

In an embodiment of the present disclosure, as shown in FIG. 20, the stiffener structure 16 includes a plurality of fourth stiffener structures 164. At least a portion of the second surface 1102 of the second portion 112 close to the edge EL of the flexible printed circuit 01 is attached to the fourth stiffener structures 164. The first surface 1101 of the second portion 112 is attached to the first stiffener structure 161 and the third stiffener structures 163, and the second surface 1102 is attached to at least the fourth stiffener structure 164.

In an embodiment of the present disclosure, as shown in FIG. 20, the fourth stiffener structures 164 and the second conductive film layer 13 are located in a same film layer. Therefore, the fourth stiffener structures 164 and the second conductive film layer 13 can be fabricated simultaneously, so that the flexible printed circuit 01 has a simple fabrication process flow.

The fourth stiffener structure 164 is at least located on the side of the second conductive structure 131 facing the edge EL of the flexible printed circuit 01. The fourth stiffener structures 164 include second end portions 1641 adjacent to the edge EL of the flexible printed circuit 01 and second connecting portions 1642 away from the edge of the flexible printed circuit 01 and connected to the second conductive structure 131. Therefore, the plurality of fourth stiffener structures 164 can be regarded as protrusions disposed on the side of the second conductive structure 131 facing the edge EL of the flexible printed circuit 01 and connected to the second conductive structure 131. For example, as shown in FIG. 18, multiple fourth stiffener structures 164 are included between the second conductive structure 131 and the edge EL located above the second conductive structure 131, multiple fourth stiffener structures 164 are included between the second conductive structure 131 and the edge EL located below the second conductive structure 131, and multiple fourth stiffener structures 164 are included between the second conductive structure 131 and the edge EL located to the right of the second conductive structure 131.

In addition, a width of the second end portion 1641 of the fourth stiffener structure 164 along the first direction X is smaller than a width of the second connecting portion 1642 along the first direction X, where the first direction X is parallel to an extending direction of the edge of the flexible printed circuit 01 adjacent to the second end portion 1641. That is, a width of an end of the fourth stiffener structure 164 adjacent to the edge of the flexible printed circuit 01 is smaller than a width of an end of the fourth stiffener structure 164 away from the edge of the flexible printed circuit 01. For example, as shown in FIG. 19, a lower end of the fourth stiffener structure 164 between the second conductive structure 131 and the edge EL below the second conductive structure 131 is the second end portion 1641, and an upper end of the fourth stiffener structure 164 is the second connecting portion 1642. In this case, the first direction X is parallel to the extending direction of the edge EL, and the first direction X is a row direction. Therefore, a width of the second end portion 1641 along the row direction is smaller than a width of the second connecting portion 1642 along the row direction. A right end of the fourth stiffener structure 164 between the second conductive structure 131 and the edge EL located to the right of the second conductive structure 131 is the second end portion 1641, and a left end of the fourth stiffener structure 164 is the second connecting portion 1642. In this case, the first direction X is parallel to the extending direction of the edge EL, and the first direction X is a column direction. Therefore, a width of the second end portion 1641 along the column direction is smaller than a width of the second connecting portion 1642 along the column direction. In conjunction with FIG. 19 and FIG. 18, an upper end of the fourth stiffener structure 164 between the second conductive structure 131 and the edge EL above the second conductive structure 131 is the second end portion 1641, and a lower end of the fourth stiffener structure 164 is the second connecting portion 1642. In this case, the first direction X is parallel to the extending direction of the edge EL, and the first direction X is the row direction. Therefore, the width of the second end portion 1641 along the row direction is smaller than the width of the second connecting portion 1642 along the row direction.

In this embodiment, the fourth stiffener structures 164 are at least a partially attached to the second portion 112 of the flexible substrate 11. That is, the portion of the flexible substrate 11 located on the side of the double-sided copper exposure region close to the edge EL of the flexible printed circuit 01 is attached to the fourth stiffener structures 164, and the fourth stiffener structures 164 can be fabricated simultaneously with the second conductive film layer 13, which can reduce the fabrication difficulty of the flexible printed circuit 01 and reduce the cost. Moreover, the second end portions of the fourth stiffener structures 164 in the same layer as the second conductive film layer 13 have a smaller width. Therefore, the provision of the fourth stiffener structures 164 can improve the thickness and toughness of the cutting position while reducing the probability of conductive burrs occurring in the fourth stiffener structures 164, thereby ensuring the reliability of the flexible printed circuit 01.

The fourth stiffener structures 164 can be integrated with the second conductive film layer 13 as an integral structure. A specific implementation of this can be referred to the solution that the third stiffener structures 163 can be integrated with the first conductive film layer 13 as an integral structure in the above embodiments, and will not be described herein again.

In addition, the material, length and shape of the fourth stiffener structure 164 can also be referred to the solutions of the material, length and shape of the third stiffener structure 163 in the above embodiments, and will not be described herein again.

FIG. 21 is a schematic diagram of a partial cross-section of another flexible printed circuit according to an embodiment of the present disclosure.

Moreover, as shown in FIG. 21, the fourth stiffener structures 164 and the second stiffener structure 162 that are stacked are included on the side of the second conductive structure 131 facing the edge EL of the flexible printed circuit 01. A specific implementation of this can be referred to the solution that the third stiffener structures 163 and the first stiffener structure 161 that are stacked are included on the side of the first conductive structure 121 facing the edge EL of the flexible printed circuit 01 in the above embodiments, and will not be described herein again.

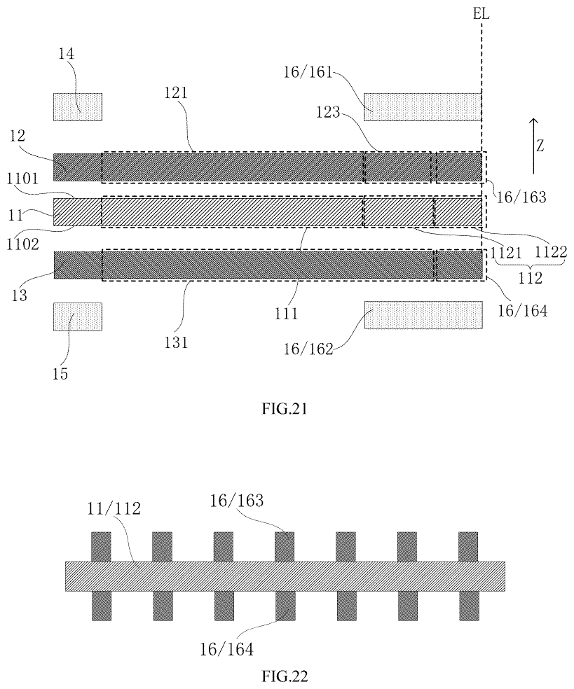

FIG. 22 is a schematic diagram of a cross-section taken along a direction E1-E2 in FIG. 11.

In an embodiment of the present disclosure, as shown in FIG. 22, in the direction Z perpendicular to the plane of the flexible printed circuit 01, the projections of the third stiffener structures 163 coincide with projections of the fourth stiffener structures 164. Therefore, a portion of the flexible printed circuit 01 which is located in the regions where the third stiffener structures 163 and the fourth stiffener structures 164 are located has a greater thickness and toughness.

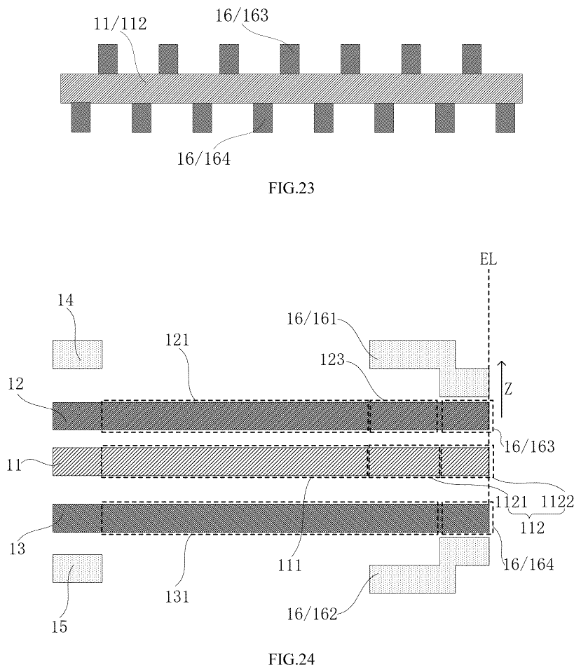

FIG. 23 is a schematic diagram of another cross-section taken along the direction E1-E2 in FIG. 11.

In an embodiment of the present disclosure, in conjunction with FIG. 18 and FIG. 23, along the direction parallel to the plane of the flexible printed circuit 01, the first end portions 1631 of the third stiffener structures 163 close to the edge EL of the flexible printed circuit 01 and the second end portions 1641 of the fourth stiffener structures 164 close to the edge EL of the flexible printed circuit 01 are arranged alternately. Therefore, more area of the flexible printed circuit 01 close to the edge EL of the flexible printed circuit 01 includes the stiffener structure 16.

FIG. 24 is a schematic diagram of a partial cross-section of another flexible printed circuit according to an embodiment of the present disclosure.

In an embodiment of the present disclosure, as shown in FIG. 9, FIG. 10, FIG. 13, FIG. 20, FIG. 21, and FIG. 24, along the direction Z perpendicular to the plane of the flexible printed circuit 01, both the first conductive structure 121 and the second conductive structure 131 do not overlap with the stiffener structure 16. Moreover, along the direction Z perpendicular to the plane of the flexible printed circuit 01, the edge of the first conductive structure 121 close to the edge EL of the flexible printed circuit 01 is aligned with the edge of the second conductive structure 131 close to the edge EL of the flexible printed circuit 01.

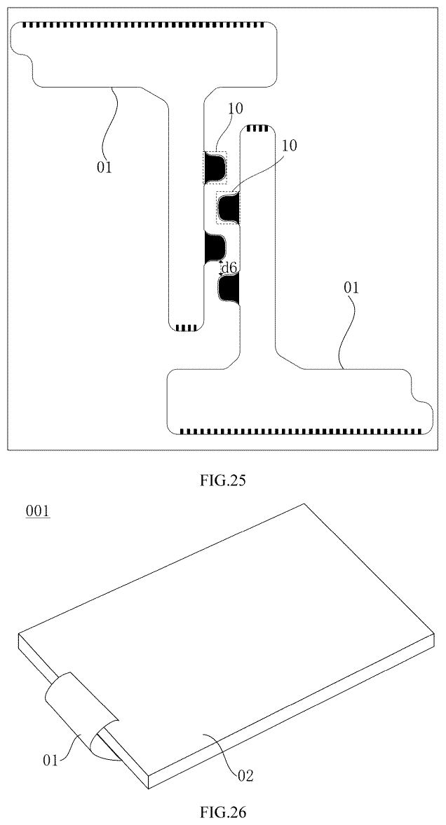

FIG. 25 is a schematic diagram of a panelization according to an embodiment of the present disclosure.

In an embodiment of the present disclosure, when the double-sided copper exposure regions 10 of adjacent flexible printed circuits 01 in the panelization are adjacent, a distance between the adjacent double-sided copper exposure regions 10 belonging to different flexible printed circuits 01 may be d6, where d6 is greater than or equal to 5 mm. In the panelization, a region between the adjacent double-sided copper exposure regions 10 belonging to different flexible printed circuits 01 is a waste region. When d6≥5 mm, the difficulty of providing the stiffener structure in the waste region is reduced, which in turn makes the thickness and toughness of the cutting position greater when performing panelization cutting to obtain the flexible printed circuit 01. In addition, while ensuring the utilization rate of the layout, the waste region between the adjacent double-sided copper exposure regions 10 belonging to different flexible printed circuits 01 can have better flatness. Therefore, when performing panelization cutting to obtain the flexible printed circuit 01, the flatness of the cutting position is better, which can reduce the punching stress and the pulling force at the copper exposure positions, and reduce the damage defects.

FIG. 26 is a schematic diagram of a display module according to an embodiment of the present disclosure.

An embodiment of the present disclosure further provides a display module 001. As shown in FIG. 26, the display module 001 includes the flexible printed circuit 01 according to any one of the above embodiments and a display panel 02, and the flexible printed circuit 01 is electrically connected to the display panel 02. The connection manner between the flexible printed circuit 01 and the display panel 02 in the display module 001 shown in FIG. 26 is merely illustrative, and the connection manner between the flexible printed circuit 01 and the display panel 02 in the display module 001 may also be other connection manners.

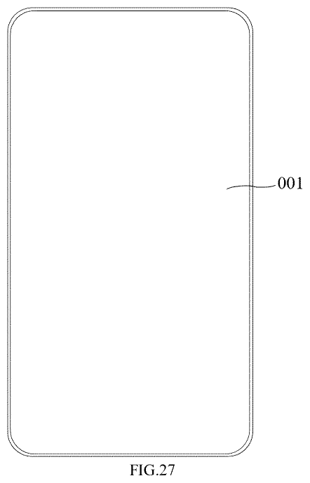

FIG. 27 is a schematic diagram of a display apparatus according to an embodiment of the present disclosure.

An embodiment of the present disclosure further provides a display apparatus. As shown in FIG. 27, the display apparatus includes the above-mentioned display panel 001. Of course, the display apparatus shown in FIG. 27 is merely illustrative, and the display apparatus may be any electronic device having a display function, such as a mobile phone, a tablet computer, a notebook computer, an e-book or a television.

The above are merely preferred embodiments of the present disclosure and are not intended to limit the present disclosure. Any modifications, equivalent substitutions, improvements, and the like made within the spirit and principle of the present disclosure shall fall within the protection scope of the present disclosure.

What is claimed is:

1. A flexible printed circuit, comprising:
a flexible substrate comprising a first surface and a second surface opposite to each other; wherein, the flexible substrate comprises a first portion and a second portion connected to each other, and the second portion is located on a side of the first portion close to an edge of the flexible printed circuit;
a first conductive film layer located on the first surface of the flexible substrate, wherein, the first conductive film layer comprises a first conductive structure attached to the first portion;
a second conductive film layer located on the second surface of the flexible substrate, wherein, the second conductive film layer comprises a second conductive structure attached to at least the first portion;
a first cover film located on a side of the first conductive film layer away from the flexible substrate, wherein, along a direction perpendicular to a plane of the flexible printed circuit, the first conductive structure does not overlap with the first cover film; and
a second cover film located on a side of the second conductive film layer away from the flexible substrate, wherein, along the direction perpendicular to the plane of the flexible printed circuit, the second conductive structure does not overlap with the second cover film;
wherein, along the direction perpendicular to the plane of the flexible printed circuit, the first conductive structure overlaps with the second conductive structure, and the first conductive film layer and the second conductive film layer do not overlap with the second portion; and at least a region of the first surface of the second portion close to the edge of the flexible printed circuit is attached to a stiffener structure.

2. The flexible printed circuit according to claim 1, wherein, the stiffener structure at least comprises a first stiffener structure, and the first stiffener structure and the first cover film are located in a same film layer.

3. The flexible printed circuit according to claim 2, wherein, a minimum distance between the first conductive structure and the edge of the flexible printed circuit is greater than or equal to 0.5 mm.

4. The flexible printed circuit according to claim 2, wherein, the stiffener structure is not positioned between the second conductive structure and the edge of the flexible printed circuit that is adjacent to the second conductive structure; and
wherein, a minimum distance between the first conductive structure and the edge of the flexible printed circuit is greater than a minimum distance between the second conductive structure and the edge of the flexible printed circuit.

5. The flexible printed circuit according to claim 4, wherein, the second portion comprises a first sub-portion and a second sub-portion, and the second sub-portion is located on a side of the first sub-portion close to the edge of the flexible printed circuit; and
wherein, the first conductive film layer comprises a third conductive structure connected to the first conductive structure, and the third conductive structure is attached to the first sub-portion; and a portion of the first stiffener structure is attached to the third conductive structure, and another portion of the first stiffener structure is attached to the first surface of the second sub-portion.

6. The flexible printed circuit according to claim 5, wherein, an edge of the third conductive structure close to the edge of the flexible printed circuit is aligned, in the direction perpendicular to the plane of the flexible printed circuit, with an edge of the second conductive structure close to the edge of the flexible printed circuit.

7. The flexible printed circuit according to claim 2, wherein, the stiffener structure comprises a second stiffener structure, and at least a portion of the second surface of the second portion close to the edge of the flexible printed circuit is attached to the second stiffener structure.

8. The flexible printed circuit according to claim 7, wherein, the second stiffener structure and the second cover film are located in a same film layer.

9. The flexible printed circuit according to claim 7, wherein, a minimum distance between the second conductive structure and the edge of the flexible printed circuit is greater than or equal to 0.5 mm.

10. The flexible printed circuit according to claim 7, wherein, an edge of the first conductive structure close to the edge of the flexible printed circuit is aligned, in the direction perpendicular to the plane of the flexible printed circuit, with an edge of the second conductive structure close to the edge of the flexible printed circuit.

11. The flexible printed circuit according to claim 1, wherein, the stiffener structure comprises a plurality of third stiffener structures, and the third stiffener structures and the first conductive film layer are located in a same film layer; the third stiffener structures comprise first end portions adjacent to the edge of the flexible printed circuit and first connecting portions away from the edge of the flexible printed circuit and connected to the first conductive structure; and
wherein, a width of the first end portion of the third stiffener structure along a first direction is smaller than a width of the first connecting portion along the first direction, and the first direction is parallel to an extending direction of the edge of the flexible printed circuit that is adjacent to the first end portion.

12. The flexible printed circuit according to claim 11, wherein, the third stiffener structures and the first conductive structure are formed as an integral structure.

13. The flexible printed circuit according to claim 12, wherein, the third stiffener structures comprise a copper film.

14. The flexible printed circuit according to claim 11, wherein, a length of the third stiffener structure along a second direction is greater than or equal to 0.2 mm, and the second direction is parallel to an arrangement direction of the second portion to which the third stiffener structure is attached and the first portion connected thereto.

15. The flexible printed circuit according to claim 11, wherein, the stiffener structure comprises a plurality of fourth stiffener structures, and at least a portion of the second surface of the second portion close to the edge of the flexible printed circuit is attached to the fourth stiffener structures.

16. The flexible printed circuit according to claim 15, wherein, the fourth stiffener structures and the second conductive film layer are located in a same film layer, and the fourth stiffener structures comprises second end portions adjacent to the edge of the flexible printed circuit and second connecting portions away from the edge of the flexible printed circuit and connected to the first conductive structure; and
wherein, a width of the second end portion of the fourth stiffener structure along the first direction is smaller than a width of the second connecting portion along the first direction, and the first direction is parallel to an extending direction of the edge of the flexible printed circuit that is adjacent to the second end portion.

17. The flexible printed circuit according to claim 15, wherein, along the direction perpendicular to the plane of the flexible printed circuit, projections of the third stiffener structures coincide with projections of the fourth stiffener structures.

18. The flexible printed circuit according to claim 15, wherein, along a direction parallel to the plane of the flexible printed circuit, the first end portions of the third stiffener structure close to the edge of the flexible printed circuit and the second end portions of the fourth stiffener structure close to the edge of the flexible printed circuit are alternately arranged.

19. The flexible printed circuit according to claim 7, wherein, along a direction perpendicular to the plane of the flexible printed circuit, both the first conductive structure and the second conductive structure do not overlap with the stiffener structure; and
wherein, along the direction perpendicular to the plane of the flexible printed circuit, an edge of the first conductive structure close to the edge of the flexible printed circuit is aligned with an edge of the second conductive structure close to the edge of the flexible printed circuit.

20. A display module, comprising a flexible printed circuit and a display panel, wherein, the flexible printed circuit is electrically connected to the display panel, and the flexible printed circuit comprises:
a flexible substrate comprising a first surface and a second surface opposite to each other; wherein, the flexible substrate comprises a first portion and a second portion connected to each other, and the second portion is located on a side of the first portion close to an edge of the flexible printed circuit;
a first conductive film layer located on the first surface of the flexible substrate, wherein, the first conductive film layer comprises a first conductive structure attached to the first portion;
a second conductive film layer located on the second surface of the flexible substrate, wherein, the second conductive film layer comprises a second conductive structure attached to at least the first portion;
a first cover film located on a side of the first conductive film layer away from the flexible substrate, wherein, along a direction perpendicular to a plane of the flexible printed circuit, the first conductive structure does not overlap with the first cover film; and
a second cover film located on a side of the second conductive film layer away from the flexible substrate, wherein, along the direction perpendicular to the plane of the flexible printed circuit, the second conductive structure does not overlap with the second cover film;
wherein, along the direction perpendicular to the plane of the flexible printed circuit, the first conductive structure overlaps with the second conductive structure, and the first conductive film layer and the second conductive film layer do not overlap with the second portion; and at least a region of the first surface of the second portion close to the edge of the flexible printed circuit is attached to a stiffener structure.
